(19) United States
(12) Patent Application Publication
(10) Pub. No.: US 2014/0209151 A1
(43) Pub. Date: Jul. 31, 2014

(54) SOLAR CELL MODULE

(71) Applicant: LG ELECTRONICS INC., Seoul (KR)

(72) Inventors: Bojoong KIM, Seoul (KR); Taeyoon KIM, Seoul (KR); Jongdae KIM, Seoul (KR); Daehee JANG, Seoul (KR)

(73) Assignee: LG ELECTRONICS INC., Seoul (KR)

(21) Appl. No.: 14/167,656

(22) Filed: Jan. 29, 2014

(30) Foreign Application Priority Data
Jan. 30, 2013 (KR) 10-2013-0010506

(51) Int. Cl. H01L 31/048; H01L 31/042

(52) U.S. Cl. CPC H01L 31/048; H02S 30/00
USPC 136/251

(57) ABSTRACT

Discussed is a solar cell module including a plurality of solar cells including a photoelectric convertor and an electrode, a circuit wiring layer having a wiring for electrically connecting the plurality of solar cells, a barrier disposed on the circuit wiring layer, the barrier partitioning areas corresponding to the plurality of solar cells, and a sealing material for bonding and sealing the plurality of solar cells, the circuit wiring layer and the barrier.

### CROSS-REFERENCE TO RELATED APPLICATION

This application claims the priority benefit of Korean Patent Application No. 10-2013-0010506, filed on Jan. 30, 2013 in the Korean Intellectual Property Office, the disclosure of which is incorporated herein by reference.

### BACKGROUND OF THE INVENTION

1. Field of the Invention

Embodiments of the invention relate to a solar cell module and, more particularly, to a solar cell module with an improved structure.

2. Description of the Related Art

In recent years, as conventional energy resources such as petroleum and coal are expected to be depleted, interest in alternative energy resources to replace these energy resources is on the rise. Of these, solar cells are attracting considerable attention as next generation cells which convert solar energy into electrical energy.

A plurality of solar cells are connected in series or parallel through a ribbon and a solar cell module is manufactured through a packaging process to protect the solar cells. An insulating film is used to prevent an undesired short-circuit when the solar cells are connected through the ribbon.

In this instance, one ribbon and one insulating film are disposed between two adjacent solar cells, thus disadvantageously increasing the number of components and requiring significant time and cost for alignment thereof.

### SUMMARY OF THE INVENTION

It is an object of the embodiments of the invention to provide a solar cell module which is capable of simplifying an alignment process and improving stability and durability.

In accordance with an aspect of the embodiment of the invention, the above and other objects can be accomplished by the provision of a solar cell module including a plurality of solar cells including a photoelectric convertor and an electrode, a circuit wiring layer having a wiring for electrically connecting the plurality of solar cells, a barrier disposed on the circuit wiring layer, the barrier partitioning areas corresponding to the plurality of solar cells, and a sealing material to bond and seal the plurality of solar cells, the circuit wiring layer and the barrier.

### BRIEF DESCRIPTION OF THE DRAWINGS

The above and other objects, features and other advantages of the embodiments of the invention will be more clearly understood from the following detailed description taken in conjunction with the accompanying drawings, in which:

FIG. 1 is a schematic exploded perspective view of a solar cell module according to an embodiment of the invention;

FIG. 2 is a partial sectional view of one solar cell in the solar cell module of FIG. 1;

FIG. 3 is a back plan view of the solar cell of FIG. 2;

FIG. 4 is a sectional view taken along the line IV-IV of the solar cell module of FIG. 1;

FIG. 5 is a sectional view illustrating a part of a solar cell module according to another embodiment of the invention;

FIG. 6 is an exploded perspective view illustrating a barrier and a circuit wiring layer of a solar cell module according to another embodiment of the invention; and

FIG. 7 is a sectional view illustrating an assembled state of a solar cell module including the barrier and the circuit wiring layer of FIG. 6.

### DETAILED DESCRIPTION OF THE EMBODIMENTS

Reference will now be made in detail to the embodiments of the invention, examples of which are illustrated in the accompanying drawings. The invention is not limited to the embodiments and the embodiments may be modified into various forms.

In the drawings, parts unrelated to the description are not illustrated for a clear and brief description of the embodiments of the invention, and the same reference numbers will be used throughout the specification to refer to the same or like parts. In the drawings, the thickness or size is exaggerated or reduced for a more clear description. In addition, the size or area of each constituent element is not limited to that illustrated in the drawings.

It will be further understood that, throughout this specification, when one element is referred to as “comprising” another element, the term “comprising” specifies the presence of another element but does not preclude the presence of other additional elements, unless context clearly indicates otherwise. In addition, it will be understood that when one element such as a layer, a film, a region or a plate is referred to as being “on” another element, the one element may be directly on the another element, and one or more intervening elements may also be present. In contrast, when one element such as a layer, a film, a region or a plate is referred to as being “directly on” another element, one or more intervening elements are not present.

Hereinafter, a solar cell module and a method for manufacturing the same according to embodiments of the invention will be described in detail with reference to the annexed drawings.

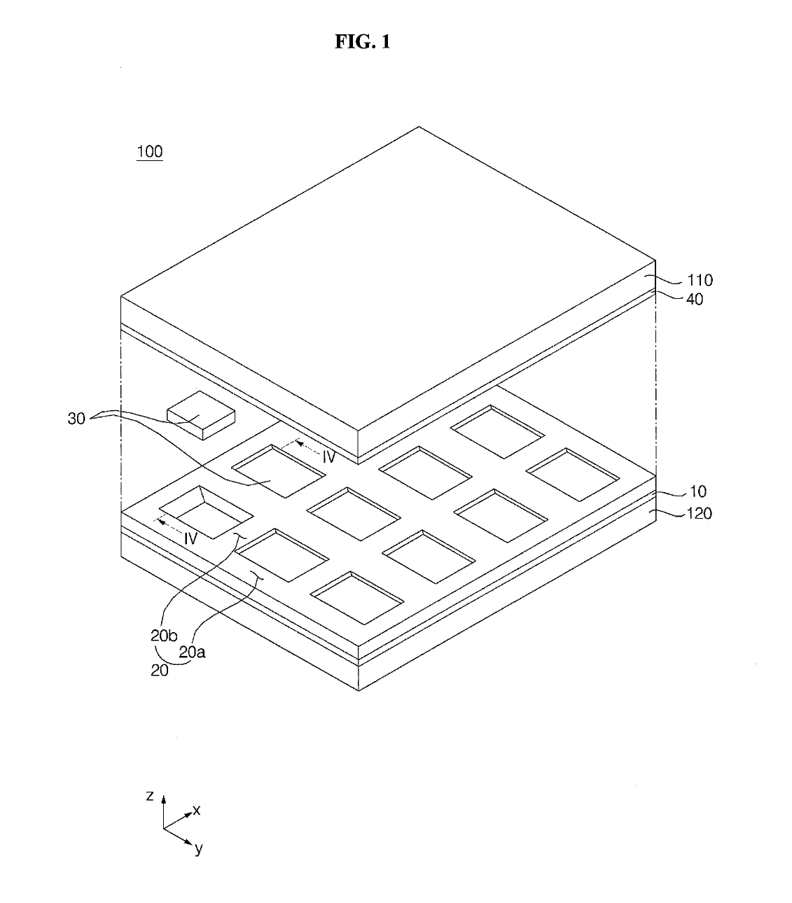

FIG. 1 is a schematic exploded perspective view of a solar cell module according to an embodiment of the invention.

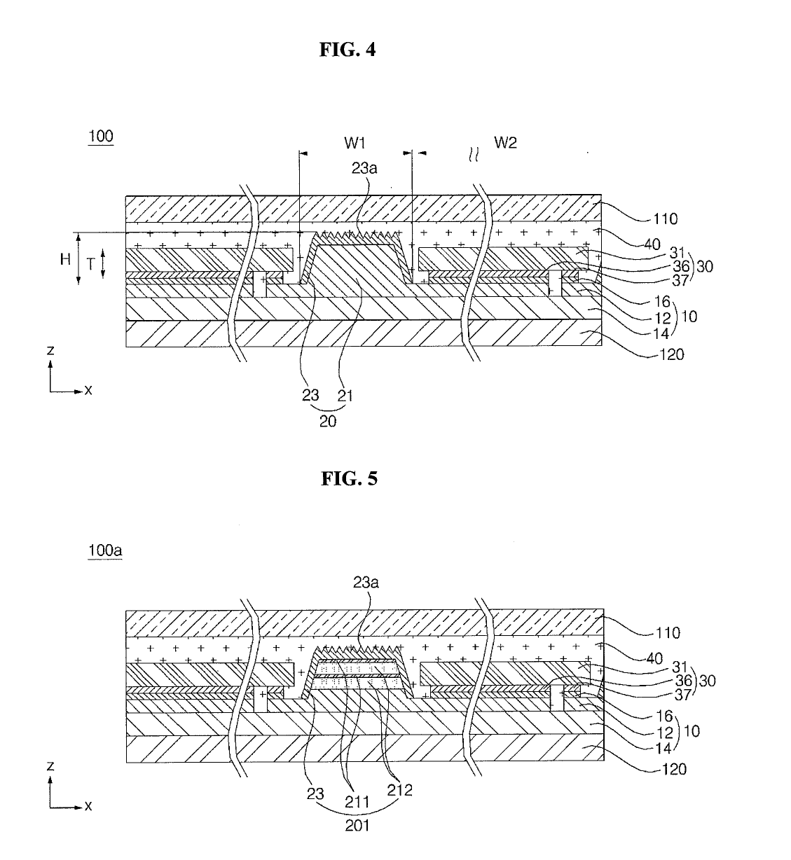

Referring to FIG. 1, the solar cell module 100 includes a circuit wiring layer 10 having a wiring (represented by reference numeral “12” in FIG. 4, hereinafter, the same will apply), a barrier 20 disposed on the circuit wiring layer 10, a plurality of solar cells 30 (or a solar cell 30) respectively disposed in areas partitioned by the barrier 20, and a sealing material 40 for sealing the circuit wiring layer 10, the barrier 20 and the solar cells 30. In addition, the solar cell module 100 may include a front substrate 110 disposed on the sealing material 40 and a back substrate 120 disposed on a back surface of the circuit wiring layer 10. This configuration will be described in more detail hereinafter.

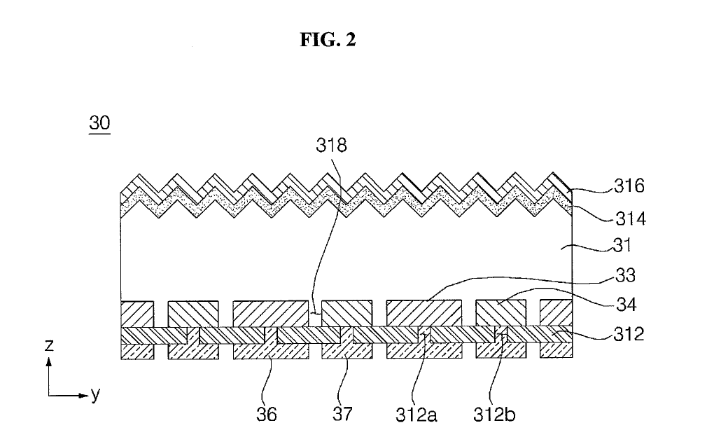

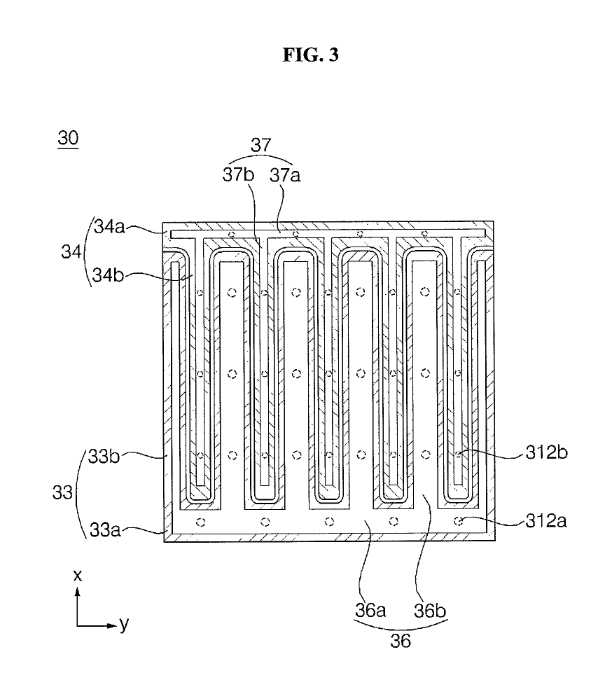

The circuit wiring layer 10 includes a wiring 12. Electrodes (represented by reference numerals “36” and “37” in FIGS. 2 and 3, hereinafter, the same will apply) of adjacent solar cells 30 are electrically connected using the wiring 12. A detailed structure of the circuit wiring layer 10 will be described in more detail with reference to FIG. 4 later.

In the embodiment of the invention, the barrier 20 partitioning areas in which the respective solar cells 30 are placed is disposed on the circuit wiring layer 10. Accordingly, the solar cells 30 are respectively placed in the areas partitioned by the barrier 20 so that the solar cells 30 are easily aligned with the wiring 12 of the circuit wiring layer 10. That is, the barrier 20 serves as an alignment mark used for alignment of the solar cell 30. In addition, the barrier 20 is formed along the solar cell 30 and also functions to physically protect the solar cell 30. As exemplified in the embodiment of the invention, the barrier 20 has a matrix shape including a first barrier 20a and a second barrier 20b which cross each other to effectively partition the areas and effectively protect the solar cell 30. However, the embodiments of the invention are not limited thereto and the barrier 20 may have a variety of structures.

The barrier 20 may be simultaneously formed with the circuit wiring layer 10 as an integral structure. Alternatively, the barrier 20 and the circuit wiring layer 10 may be separately formed and then integrally bonded to the circuit wiring layer 10. Structures of the circuit wiring layer 10 and the barrier 20 will be described in detail with reference to FIG. 4 later.

The solar cells 30 respectively placed in the areas partitioned by the barrier 20 may have a structure in which they are electrically connected through the wiring 20 of the circuit wiring layer 10 on a surface (that is, back-surface electrode type structure). That is, the solar cell 30 according to the embodiment of the invention may have a back-surface electrode type structure in which two electrodes 36 and 37 connected to a photoelectric convertor are spaced from each other on a back surface of the photoelectric convertor. An example of the solar cell 30 having the back-surface electrode type structure will be described in detail with reference to FIGS. 2 and 3 later.

The circuit wiring layer 10, the barrier 20 and the solar cell 30 are bonded to one another and sealed by the sealing material 40. That is, after the barrier 20 is disposed on the circuit wiring layer 10, the solar cell 30 is placed in the area partitioned by the barrier 20, and the sealing material 40 is disposed on the barrier 20 and the solar cell 30. In this instance, the front substrate 110 and the back substrate 120 may also be laminated.

When the resulting structure is pressed while heat is applied thereto, the sealing material 40 is softened and fills areas between the solar cell 30 and the barrier 20. As a result, the sealing material 40 is disposed from an area provided above the circuit wiring layer 10 and to an area provided above the solar cell 30 and the barrier 20 while filling areas between the solar cell 30 and the barrier 20. Then, the circuit wiring layer 10, the barrier 20 and the solar cell 30 are physically and chemically bonded to one another (the front substrate 110 and/or the back substrate 120 are also bonded when the front substrate 110 and/or the back substrate 120 are laminated). The solar cell module 100 is sealed to prevent presence of additional air therein and thereby efficiently block moisture or oxygen which may have a negative effect on the solar cell 30.

The sealing material 40 may be composed of a variety of materials capable of bonding and sealing various components. For example, the sealing material 40 may be composed of an ethylene vinyl acetate (EVA) copolymer resin, polyvinyl butyral, a silicone resin, an ester resin, an olefin resin or the like, but the embodiments of the invention are not limited thereto. Accordingly, the sealing material 40 may bond and seal the circuit wiring layer 10, the barrier 20 and the solar cell 30 by a method other than lamination and may be composed of a variety of materials other than the materials described above.

Preferably, but not necessarily, the front substrate 110 is disposed on the sealing material 40 so that the front substrate 110 transmits sunlight and is formed of a reinforced glass so that the solar cell 30 is protected from shock. In addition, more preferably, the front substrate 110 is a low-iron reinforced glass having a low iron content so as to prevent reflection of sunlight and to improve transmittance of the sunlight, but the embodiments of the invention are not limited thereto.

The back substrate 120 is a layer which protects the solar cell 30 on the back surface of the solar cell 30 and performs waterproofing, insulating and UV blocking functions. The back substrate 120 is provided in sheet form, thus reducing cost, volume, weight and the like. For example, the back substrate 120 may be a tedlar/PET/tedlar (TPT) type, but the embodiments of the invention are not limited thereto. In addition, the back substrate 120 is formed of a highly reflective material so that it reflects sunlight incident from the front substrate 110 and the sunlight is reused. However, the embodiments of the invention are not limited thereto and a solar cell module 100 having a two-surface type structure may be implemented by forming a back sheet 120 using a transparent material, upon which sunlight is incident. However, the back substrate 120 is not an indispensable component and may be removed, if necessary. The back substrate 120 may be bonded to the circuit wiring layer 10 through a separate sealing material disposed over the entire area between the back substrate 120 and the circuit wiring layer 10. However, the embodiments of the invention are not limited thereto and the circuit wiring layer 10 may be directly formed on the back substrate 120 by deposition, printing or the like and various modifications are possible.

As described above, the solar cell 30 has the back-surface electrode type structure and an example of the solar cell 30 having the structure will be described in detail with reference to FIGS. 2 and 3.

The solar cell 30 of the embodiment of the invention is a semiconductor device which converts solar energy into electrical energy and may be a silicon solar cell, but the embodiments of the invention are not limited thereto. The photoelectric convertor of the solar cell 30 according to the embodiment of the invention may have a structure in which first and second conductive areas 33 and 34 having different conductive types are disposed on the back surface of the semiconductor substrate 31. This structure will be described in detail with reference to FIGS. 2 and 3.

FIG. 2 is a partial sectional view of one solar cell in the solar cell module of FIG. 1 and FIG. 3 is a back plan view of the solar cell of FIG. 2.

Referring to FIG. 2, in the embodiment of the invention, each solar cell 30 includes a semiconductor substrate 31, first and second conductive areas 33 and 34 spaced from each other on a surface (back surface) of the semiconductor substrate 31, and first and second electrodes 36 and 37 electrically connected to the first and second conductive areas 33 and 34. The solar cell 30 may further include a passivation film 312 for passivating the first and second conductive areas 33 and 34. This will be described in more detail.

The semiconductor substrate 31 may include a variety of semiconductor materials. For example, the semiconductor substrate 31 may include silicon containing a first conductive type impurity. The silicon may be monocrystalline silicon or polycrystalline silicon and the first conductive type may be n-type, for example. That is, the semiconductor substrate 31 may be formed of monocrystalline silicon or polycrystalline silicon containing a Group V element such as phosphorous (P), arsenic (As), bismuth (Bi) or antimony (Sb). However, the embodiments of the invention are not limited thereto and the semiconductor substrate 31 may be p-type.

Front and back surfaces of the semiconductor substrate 31 may be subjected to texturing and thus have protruded and depressed portions or an uneven surface having, for example, a pyramidal shape. When surface roughness is increased due to the protruded and depressed portions or the uneven surface formed on the front surface of the semiconductor substrate 31 through the texturing, reflectivity of light incident through the front surface of the semiconductor substrate 31 can be reduced. Accordingly, a dose of light which reaches a pn junction can be increased and light loss can thus be minimized.

Although a configuration in which only the front surface of the semiconductor substrate 31 is subjected to texturing is shown in the drawing, the embodiments of the invention are not limited thereto. At least one of front and back surfaces may be textured.

In the embodiment of the invention, a p-type first conductive area 33 and an n-type second conductive area 34 having different conductive types are formed on the back surface of the semiconductor substrate 31. The first conductive area 33 and the second conductive area 34 may be spaced from each other via an isolation area 318 so as to prevent shunting. The first conductive area 33 and the second conductive area 34 may be spaced from each other by a predetermined distance (for example, several tens of μm to several hundreds of μm) through the isolation area 318. In addition, the first conductive area 33 and the second conductive area 34 may have identical or different thicknesses. The embodiments of the invention are not limited with regard to the distance and thicknesses of the first and second conductive areas 33 and 34.

The first conductive area 33 may be formed by doping (for example, ion implantation) with a p-type impurity and the second conductive area 34 may be formed by doping (for example, ion implantation) with an n-type impurity. The p-type dopant may be a Group III element (such as B, Ga or In) and the n-type dopant may be a Group V element (such as P, As, or Sb), but the embodiments of the invention are not limited thereto. Accordingly, first and second conductive areas 33 and 34 may be prepared by forming a layer including amorphous silicon having a p-type impurity and a layer including amorphous silicon having an n-type impurity on the back surface of the semiconductor substrate 31. The first and second conductive areas 33 and 34 may be formed by various other methods.

Plane shapes of the first conductive area 33 and the second conductive area 34 will be described with reference to FIG. 3. FIG. 3 is a back plan view illustrating the first and second conductive areas 33 and 34 and the first and second electrodes 36 and 37 of a solar cell according to an embodiment of the invention. In FIG. 3, the passivation film 312 is not illustrated for clarity and clearer depiction of the underlying structure.

The first conductive area 33 may include a first stem 33a formed along a first edge (lower edge in the drawing) of the semiconductor substrate 31, and a plurality of first branches 33b extending from the first stem 33a toward the second edge (upper edge in the drawing) opposite to the first edge. In addition, the second conductive area 34 includes a second stem 34a formed along the second edge of the semiconductor substrate 31, and a plurality of second branches 34b extending from the second stem 34a between the first branches 33b toward the first edge. The first branches 33b of the first conductive area 33 may alternate with the second branches 34b of the second conductive area 34. This configuration increases a pn junction area.

An area of the first conductive area 33, which is p-type, may be greater than an area of the second conductive area 34 which is n-type. For example, the areas of the first and second conductive areas 33 and 34 may be controlled by changing widths of the first and second stems 33a and 34a and/or the first and second branches 33b and 34b.

In the embodiment of the invention, carriers are collected only on the back surface and a horizontal width of the semiconductor substrate 31 is greater than the thickness of the semiconductor substrate 31. However, the area of the p-type first conductive area 33 may be greater than that of the n-type second conductive area 34 while taking into consideration the fact that an electron movement speed is greater than a hole movement speed. In this instance, while taking into consideration the fact that a ratio of electron movement speed to hole movement speed is about 3:1, the area of the first conductive area 33 may be 2 to 6 fold of the area of the second conductive area 34. That is, this area ratio optimizes design of the first and second conductive areas 33 and 34 in consideration of electron and hole movement speeds.

Referring to FIG. 2 again, the passivation film 312 may be formed on the first and second conductive areas 33 and 34. The passivation film 312 passivates defects present on the back surface of the semiconductor substrate 31 (that is, surfaces of first and second conductive areas 33 and 34) and thereby removes recombination sites of minority carriers. As a result, an open-circuit voltage (Voc) of the solar cell 30 can be improved.

In the embodiment of the invention, the passivation film 312 corresponding to the first and second conductive areas 33 and 34 is provided as a single layer having one material and one type of passivation film 312 is thus formed. However, the embodiments of the invention are not limited thereto and the passivation film 312 may include a plurality of passivation films including materials respectively corresponding to the first and second conductive areas 33 and 34. The material for the passivation film 312 may include at least one selected from the group consisting of silicon oxide, silicon nitride, silicon oxide nitride, aluminum oxide, hafnium oxide, zirconium oxide, MgF₂, ZnS, TiO₂ and CeO₂.

A first electrode 36 connected to the first conductive area 33 and a second electrode 37 connected to the second conductive area 34 may be formed on the passivation film 312. More specifically, the first electrode 36 may be connected to the first conductive area 33 by a first via hole 312a passing through the passivation film 312 and the second electrode 37 may be connected to the second conductive area 34 by a second via hole 312b passing through the passivation film 312.

In this instance, as shown in FIG. 3, the first electrode 36 may include a stem 36a formed corresponding to the stem 33a of the first conductive area 33 and a branch 36b formed corresponding to the branch 33b of the first conductive area 33. Similarly, the second electrode 37 may include a stem 37a formed corresponding to the stem 34a of the second conductive area 34 and a branch 37b formed corresponding to the branch 34b of the second conductive area 34. The first electrode 36 (more specifically, stem 36a of the first electrode 36) is disposed at one side (lower side in the drawing) of the semiconductor substrate 31, and the second electrode 37 (more specifically, the step 37a of the second electrode 37) is disposed at another side (lower side in the drawing) of the semiconductor substrate 31. However, the embodiments of the invention are not limited thereto and the first electrode 36 and the second electrode 37 may have a variety of plane shapes.

The first and second electrodes 36 and 37 may include various materials and may, for example, include a single metal layer or a laminate of a plurality of metal layers, but the embodiments of the invention are not limited thereto.

Meanwhile, a front surface field layer 314 may be formed on the front surface of the semiconductor substrate 31. The front surface field layer 314 is an area in which impurity is doped at a dose higher than the semiconductor substrate 31 and performs functions similar to the back surface field (BSF) layer. That is, the front surface field layer 314 prevents or reduces a phenomenon in which electrons and holes separated by light, such as sunlight, are recombined on the front surface of the semiconductor substrate 31 and decay.

An anti-reflective film 316 may be formed on the front surface field layer 314. The anti-reflective film 316 may be formed over the entire front surface of the semiconductor substrate 31. The anti-reflective film 316 reduces reflectivity of light incident upon the front surface of the semiconductor substrate 31 and passivates defects present on the surface or in the bulk of the front surface field layer 314.

The anti-reflective film 316 reduces reflectivity of light incident upon the front surface of the semiconductor substrate 31, thereby increasing a dose of light reaching a junction formed at the interface between the semiconductor substrate 31 and the first or second conductive areas 33 and 34. Accordingly, short-circuit current (Isc) of the solar cell 30 can be increased. In addition, the anti-reflective film 316 passivates defects, removes recombination sites of minority carriers and thereby increases an open-circuit voltage (Voc) of the solar cell 30. As such, the anti-reflective film 316 increases open-circuit voltage and short-circuit current of the solar cell 30 and thereby improves conversion efficiency of the solar cell 30.

The anti-reflective film 316 may be formed of various materials. For example, the anti-reflective film 316 may have a single film structure including one selected from the group consisting of a silicon nitride film, a silicon nitride film containing hydrogen, a silicon oxide film, a silicon oxide nitride film, MgF₂, ZnS, TiO₂ and CeO₂, or a multilayer film structure including two or more thereof, but the embodiments of the invention are not limited thereto and the anti-reflective film 316 may include a variety of materials.

Electrodes 36 and 37 are not provided on the front surface of the solar cell 30 having the back-surface electrode type structure, thus minimizing shading loss and greatly improving efficiency of the solar cell 30.

The structure of the circuit wiring layer 10, a structure of electrical connection between the solar cells 30 using the circuit wiring layer 10, the shape of the barrier 20 and the like will be described in detail with reference to FIG. 4. FIG. 4 is a sectional view taken along the line IV-IV of the solar cell module of FIG. 1. For accurate description and simple illustration, the solar cell 30 is simply illustrated in FIG. 4 and only the semiconductor substrate 31 and the electrodes 36 and 37 of the solar cell 30 are illustrated.

The circuit wiring layer 10 may include an insulating film 14 and a wiring 12 which is formed on the insulating film 14 and electrically connects the solar cells 30.

The insulating film 14 may be formed of a resin which has insulating properties and enables stable formation of the wiring 12. For example, the insulating film 14 may be formed of a variety of resins such as polyimide or polyester.

The wiring 12 may be formed by patterning a metal layer formed on the insulating film 14. The wiring 12 includes an electrically conductive metal to facilitate electrical connection between adjacent solar cells 30. The wiring 12 may be selected from a variety of metals such as gold, silver, titanium, platinum, nickel, chromium, aluminum and copper. For example, copper which exhibits superior electrical conductivity and is cheap may be used.

A conductive film 16 is disposed on the wiring 12 to electrically and physically connect the wiring 12 to electrodes 36 and 37 of the solar cell 30. The conductive film 16 may be a film including epoxy, acryl, polyimide, polyester or polycarbonate in which conductive particles including gold, silver, nickel, copper or the like having superior conductivity are dispersed. Upon pressing while applying heat using the conductive film 16, the conductive particles are exposed to the outside of the film and electrodes 36 and 37 of the solar cell 30 are electrically connected to the wiring 12 through the exposed conductive particles. By using the conductive film 16, process temperature is lowered and bending of the solar cell 30 is thus prevented, but the embodiments of the invention are not limited thereto. The wiring 12 may be electrically and physically connected to electrodes 36 and 37 of the solar cell 30 by a variety of methods other than the conductive film 16.

The first electrode 36 (or second electrode 37) of one solar cell 30 and the second electrode 37 (or first electrode 36) of another solar cell 30 adjacent thereto are electrically connected through the wiring 12 of the circuit wiring layer 10. As a result, the solar cells 30 are connected in series in one direction (x-axis direction in the drawing). The solar cells 30 which are connected in series and constitute one row may be connected such that they alternate with one another at both ends. As a result, the solar cells 30 may be entirely connected in series, but the embodiments of the invention are not limited thereto. The solar cell 30 may be connected in various ways, such as, in series or parallel.

In the embodiment of the invention, the barrier 20 may include a metal portion 21 integrated with the wiring 12 of the circuit wiring layer 10 and an insulating portion 23 surrounding the metal portion 21. The wiring 12 of the circuit wiring layer 10 may be integrally formed with the metal portion 21 of the barrier 20 by patterning and etching the metal layer disposed on the insulating film 14. In addition, after the metal portion 21 is formed, the insulating portion 23 may be formed by applying an insulating material by a method such as printing such that the insulating portion 23 surrounds the metal portion 21.

When the metal portion 21 is disposed in the insulating portion 23 as described above, physical strength of the barrier 20 can be improved. In addition, the metal portion 21 reflects incident light toward an area which does not contribute to photoelectric conversion and guides the light toward the solar cell 30 which contributes to photoelectric conversion. As a result, dose of light incident upon the solar cell 30 is increased and efficiency of the solar cell 30 is thus improved. For such a reflection effect, a side surface of the metal portion 21 (or barrier 20) may be inclined. For example, an area of the metal portion 21 gradually decreases toward the front substrate 110, thus enabling the metal portion 21 to effectively reflect light. The inclined side surface of the metal portion 21 may be easily formed by controlling process conditions during etching of the metal layer.

The protruded and depressed portions or the uneven surface 23a are formed on the upper surface of the insulating portion 23 by texturing so as to reduce reflection of light passing through the insulating portion 23 and traveling toward the solar cell 30. The protruded and depressed portions or the uneven surface 23a may be formed by a variety of methods such as chemical etching or physical etching and may have a variety of shapes such as pyramidal, notch and round shapes.

In the embodiment of the invention, the barrier 20 includes the metal portion 21 integrated with the wiring 12 and the insulating portion 23 surrounding the metal portion 21, but the embodiments of the invention are not limited thereto. Accordingly, the barrier 20 may include only the insulating portion 23 and the insulating portion 23 may be integrated with the circuit wiring layer 10. The circuit wiring layer 10 and the barrier 20 having the structure may be formed by patterning an insulating layer in an insulating film 14 including a metal layer and the insulating layer to form the insulating portion 23 and then patterning the metal layer to form the metal portion 21. Various other structures and formation methods may be used.

In the embodiment of the invention, a height (H) of the barrier 20 may be equal to or greater than a thickness (T) of the solar cell 30. As a result, the entire side surface of the solar cell 30 can be protected and the solar cell 30 can be inserted into the area partitioned by the barrier 20. For example, a ratio (H/T) of the height (H) of the barrier 20 to the thickness (T) of the solar cell 30 may be 1.0 to 1.3. When the ratio exceeds 1.3, the height of the barrier 20 is excessively great and stability of the barrier 20 may be deteriorated and there may be a difficulty in producing the barrier 20.

For example, the height (H) of the barrier 20 may be 10 μm to 200 μm. When the height (H) of the barrier 20 exceeds 200 μm, the height of the barrier 20 is excessively large and stability of the barrier 20 may be deteriorated and there may be a difficulty in producing the barrier 20. When the height (H) of the barrier 20 is lower than 10 μm, it is smaller than the thickness (T) of the solar cell 30 or may not sufficiently protect the solar cell 30 and/or may not sufficiently exert alignment mark function. However, the height (H) of the barrier 20 may be variably changed according to the thickness of the solar cell 30 or the like.

A ratio (W1/W2) of a width (W1) of the barrier 20 to a width (W2) of the solar cell 30 may be 0.3 or less. When the ratio (W1/W2) exceeds 0.3, an area of the barrier not contributing to photoelectric conversion is excessively large, thus deteriorating the efficiency of the solar cell module 100. In the invention of the invention, a lower limit of the ratio (W1/W2) is not limited to a predetermined level. In addition, the width (W1) of the barrier 20 may be greater than a line width of electrodes 36 and 37 of the solar cell 30. When the width (W1) of the barrier 20 is smaller than the line width of the electrodes 36 and 37, physical stability may be deteriorated. For example, the width (W1) of the barrier 20 may be 10 mm or less (more specifically, 5 mm or less, for example, 2 mm or less) and may be 0.05 mm or more, but the embodiments of the invention are not limited thereto. The width (W1) of the barrier 20 may be varied in consideration of height of the barrier 20, the width (W2) of the solar cell 30 and the like.

When the solar cells 30 are disposed on the circuit wiring layer 10 through the barrier 20 partitioning areas respectively corresponding to the solar cells 30, the barrier 20 may be used as an alignment mark. As a result, alignment of the solar cell 30 is improved and simplified and cost is reduced. In addition, the barrier 20 functions to physically protect the solar cell 30 and thereby improves stability and durability of the solar cell module 100.

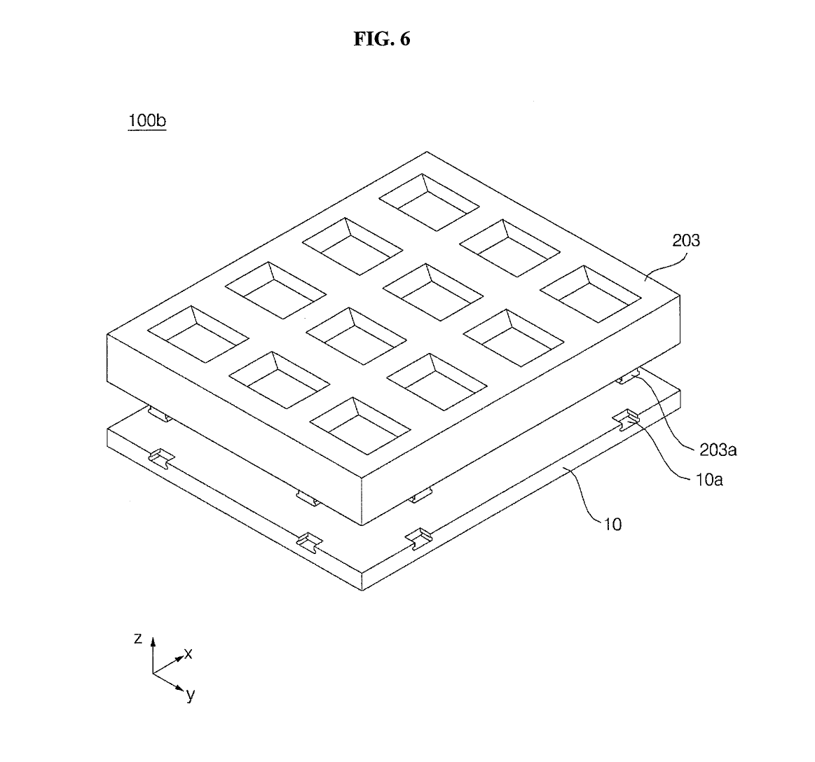

Hereinafter, a solar cell module according to another embodiment of the invention will be described in detail with reference to FIGS. 5 and 6.

FIG. 5 is a sectional view illustrating a part of a solar cell module according to another embodiment of the invention.

Referring to FIG. 5, the solar cell module 100a according to the embodiment of the invention includes a barrier 201 include a plurality of metal portions 211 and at least one intermediate portion 212 disposed between the metal portions 211. The intermediate portion 212 may be composed of an insulating layer including a resin enabling a thick film to be easily formed. The intermediate portion 212 having a sufficiently desired height can be formed, although a height of the barrier 201 should be great.

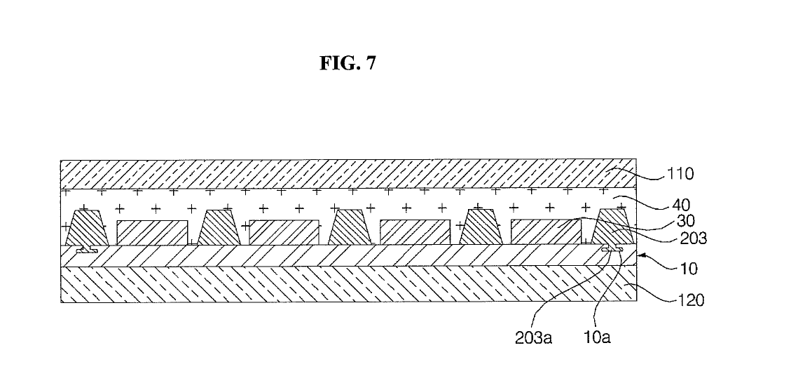

FIG. 6 is an exploded perspective view illustrating a barrier and a circuit wiring layer of a solar cell module according to another embodiment of the invention and FIG. 7 is a sectional view illustrating an assembled state of a solar cell module including the barrier and the circuit wiring layer of FIG. 6. For accurate description and simple illustration, only the circuit wiring layer 10 and the solar cell 30 are schematically shown in FIG. 7 and a detailed structure thereof is similar to that shown in FIG. 4.

Referring to FIGS. 6 and 7, in the solar cell module 100b according to the embodiment of the invention, a barrier 203 is separately formed from the circuit wiring layer 10 and is integrally bonded to the circuit wiring layer 10. For example, the barrier 203 may have a matrix structure. As shown in FIG. 6, the barrier 203 may be formed of only an insulating material. Alternatively, similar to the embodiment shown in FIG. 4, a metal portion is disposed in the barrier 203 and an insulating material surrounds the metal portion. Alternatively, similar to the embodiment shown in FIG. 5, a plurality of metal portions and a plurality of intermediate portions alternate with one another in the barrier 203 and an insulating material surrounds the metal portions and the intermediate portions.

The barrier 203 is provided with a coupling protrusion 203a bonded to the barrier 203 and the circuit wiring layer 10 is provided with a coupling recess 10a corresponding thereto. By injection-coupling the coupling protrusion 203a to the coupling recess 10a, the barrier 203 is preliminarily fixed on the circuit wiring layer 10. Then, by entirely sealing the solar cell 30 using the sealing material 40, the circuit wiring layer 10, the barrier 203 and the solar cell 30 can be easily bonded and sealed.

In the embodiments of the invention, the barrier 203 is separately formed from the circuit wiring layer 10 and the barrier 203 is thus easily manufactured and integrally bonded to the circuit wiring layer 10 although the barrier 203 has a large thickness. Accordingly, manufacture of the solar cell module is simplified and cost is effectively reduced.

According to embodiments, when the solar cells are disposed on the circuit wiring layer through the barrier partitioning areas corresponding to respective solar cells, the barrier may be used as an alignment mark. As a result, alignment of the solar cell is improved, the alignment process is simplified and cost is reduced. In addition, the barrier functions to physically protect the solar cell and ensure stability and durability of the solar cell module.

Although the example embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A solar cell module comprising:
a plurality of solar cells comprising a photoelectric convertor and an electrode;
a circuit wiring layer having a wiring for electrically connecting the plurality of solar cells;
a barrier disposed on the circuit wiring layer, the barrier partitioning areas corresponding to the plurality of solar cells; and
a sealing material to bond and seal the plurality of solar cells, the circuit wiring layer and the barrier.

2. The solar cell module according to claim 1, wherein the barrier comprises a first barrier and a second barrier crossing each other to partition the areas corresponding to the plurality of solar cells.

3. The solar cell module according to claim 1, wherein an upper surface of the barrier has protruded and depressed portions or an uneven surface formed by texturing.

4. The solar cell module according to claim 1, wherein the barrier comprises a metal portion and an insulating portion surrounding the metal portion.

5. The solar cell module according to claim 4, wherein an upper surface of the insulating portion has protruded and depressed portions or an uneven surface formed by texturing.

6. The solar cell module according to claim 4, wherein the metal portion is integrated with the wiring of the circuit wiring layer.

7. The solar cell module according to claim 4, wherein the metal portion comprises a plurality of metal portions,
wherein the barrier comprising at least one intermediate portion disposed between the plurality of metal portions, and
the at least one intermediate portion includes an insulating layer.

8. The solar cell module according to claim 1, wherein a side surface of the barrier is inclined.

9. The solar cell module according to claim 1, wherein a height of the barrier is equal to or greater than a thickness of at least one of the plurality of solar cells.

10. The solar cell module according to claim 1, wherein a ratio of a height of the barrier to a thickness of at least one of the plurality of solar cells is 1.0 to 1.3.

11. The solar cell module according to claim 1, wherein a height of the barrier is 10 μm to 200 μm.

12. The solar cell module according to claim 1, wherein a ratio of a width of the barrier to a width of at least one of the plurality of solar cells is 0.3 or less.

13. The solar cell module according to claim 1, wherein a width of the barrier is 10 mm or less and a width of the barrier is greater than a line width of the electrode of at least one of the plurality of solar cells.

14. The solar cell module according to claim 1, wherein the barrier is fixed to the circuit wiring layer by insertion coupling.

15. The solar cell module according to claim 1, wherein the barrier comprises a coupling protrusion,
the circuit wiring layer comprises a coupling recess into which the coupling protrusion is inserted, and
the barrier is fixed onto the circuit wiring layer by coupling the coupling protrusion to the coupling recess.

16. The solar cell module according to claim 1, wherein each of the plurality of solar cells further comprises a semiconductor substrate, and first and second conductive areas formed on a back surface of the semiconductor substrate, and
the electrode comprises first and second electrodes disposed on the back surface of the semiconductor substrate, the first and second electrodes respectively connected to the first and second conductive areas.

17. The solar cell module according to claim 1, further comprising a conductive film disposed between the electrode and the wiring, the conductive film bonding the electrode to the wiring and electrically connecting the electrode to the wiring.

18. The solar cell module according to claim 1, further comprising:
a front substrate disposed on the sealing material; and
a back substrate disposed on a surface of the circuit wiring layer opposite to another surface of the circuit wiring layer on which the plurality of solar cells and the barrier are disposed.

19. The solar cell module according to claim 18, wherein the circuit wiring layer further comprises an insulating film disposed on the back substrate, and
the wiring is disposed on the insulating film.

20. A solar cell module comprising:
a plurality of solar cells;
a barrier to partition areas respectively corresponding to the plurality of solar cells; and
a sealing material to bond and seal the plurality of solar cells and the barrier.
